(19) United States
(12) Patent Application Publication
(10) Pub. No.: US 2013/0118536 A1
(43) Pub. Date: May 16, 2013

(54) ULTRASONIC PRECISION CLEANING APPARATUS

(71) Applicants: Yang-Lae Lee, Daejeon (KR); Eui-Su Lim, Daejeon (KR); Hyun-Se Kim, Daejeon (KR); Sang-Yul Kim, Daejeon (KR); Gi-Bum Kil, Daejeon (KR)

(72) Inventors: Yang-Lae Lee, Daejeon (KR); Eui-Su Lim, Daejeon (KR); Hyun-Se Kim, Daejeon (KR); Sang-Yul Kim, Daejeon (KR); Gi-Bum Kil, Daejeon (KR)

(73) Assignee: KOREA INSTITUTE OF MACHINERY & MATERIALS, Daejeon (KR)

(21) Appl. No.: 13/520,838

(22) PCT Filed: May 31, 2010
(86) PCT No.: PCT/KR10/03459

§ 371 Date: Jul. 6, 2012

(51) Int. Cl. B08B 3/12; H01L 21/02

(52) U.S. Cl. CPC B08B 3/12; H01L 21/02041
USPC 134/115 R

(57) ABSTRACT

Disclosed is an ultrasonic cleaning apparatus, which generates uniform sound pressure across a wide area of a piezoelectric element without the sound pressure being concentrated into the middle of the piezoelectric element to thereby increase cleaning efficiency without damage of an object to be cleaned. The ultrasonic precision cleaning apparatus includes: a cleaning solution supplier for supplying a cleaning solution to an object to be cleaned; a transmitter (or transducer) having a piezoelectric element having a ceramic body and upper and lower electrodes respectively deposited to upper and lower portions of the ceramic body and producing ultrasonic waves, an ultrasonic waveguide coupled to a tip of the piezoelectric element, placed opposite to the object to be cleaned and transmitting the ultrasonic waves produced from the piezoelectric element to the object to be cleaned, a housing and a power line, wherein the piezoelectric element or the middle of the ultrasonic waveguide is formed with a vertical hole.

### TECHNICAL FIELD

The present invention relates to an ultrasonic cleaning apparatus, and more particularly, to an ultrasonic cleaning apparatus, which generates uniform sound pressure across a wide area of a piezoelectric element without the sound pressure being concentrated into the middle of the piezoelectric element to thereby increase cleaning efficiency without damage of an object to be cleaned.

### BACKGROUND ART

One of the most basic techniques in semiconductor fabrication processes is a cleaning technique. The semiconductor fabrication process includes many process steps to form a surface of a wafer, and in each process step, various contaminants are generated and remain in the semiconductor wafer and a semiconductor fabrication apparatus and these remaining contaminants cause defects in device pattern formed on the wafer to thereby lower the reliability of the device.

Therefore, it is required to remove the contaminants by cleaning the semiconductor wafer and the semiconductor fabrication apparatus mechanically and chemically in each process step.

A chemical cleaning is to remove the contaminants on the surface by washing, etching and oxidation-reduction reaction, and employs various chemicals or gases.

A mechanical cleaning is to release deposits by ultrasonic energy, sweep off the deposits by a brush or removing the deposits using high pressure water.

For efficient cleaning, an ultrasonic cleaning is generally used in which both mechanical cleaning and chemical cleaning are combined with each other.

That is, the ultrasonic cleaning is to remove the contaminant deposited on the object to be cleaned and prevent the removed contaminant from being deposited again by mechanical means (ultrasonic wave) and chemical means (chemical cleaning solution).

The mechanical phenomenon by ultrasonic wave means that caused by cavitation of an ultrasonic wave, and the cavitation is the phenomenon in that microbubbles are produced and dissipated by pressure of the ultrasonic wave when an ultrasonic energy is transmitted in a solution, and accompanies very large pressure (tens to hundreds atmospheric pressure) and high temperature (hundreds to thousands degrees).

In this cavitation, the microbubbles are produced and dissipated repetitively within an extremely short time (one-tens of thousandth to hundreds of thousandth of a second) to generate a shock wave, and by this shock wave, invisible inner deep portion of the object to be cleaned, which is immersed in a solution, can be cleaned within a short time.

Actually, in addition to the shock energy caused by the cavitation, agitation effect and thermal action by radiation pressure of the ultrasonic itself causes synergy with detergent to thereby result in high cleaning effect.

The ultrasonic cleaning is mainly used to clean or rinse object to be cleaned such as a glass substrate for LCD, a semiconductor wafer and a magnetic disk for data storage.

A technique for the ultrasonic cleaning is disclosed in Korean Patent Application No. 10-2006-0102511 (Title: cleaning apparatus using ultrasonic wave) by the present assignee.

This technique includes a cleaning solution supplier 100 and a transmitter (or transducer) 200 as shown in FIGS. 1 and 2.

Herein, the cleaning solution supplier 100 is placed above an object 300 to be cleaned with a predetermined gap therebetween and supplies cleaning solution.

The transmitter (or transducer) 200 is placed opposite to the object 300 to be cleaned and produces ultrasonic waves, and the produced ultrasonic waves are transmitted to the object 300 through the cleaning solution.

At this time, the transmitter (or transducer) 200 is configured so that the ultrasonic waves produced in a piezoelectric element 210 are transmitted to the object 300 to be cleaned through an ultrasonic waveguide 220 in a near field region as shown in FIG. 1, or is configured so that the ultrasonic waves produced in the piezoelectric element 210 are transmitted to the object 300 to be cleaned through the ultrasonic waveguide 220 in a far field region as shown in FIG. 2.

Herein, the piezoelectric element 210 is that oscillates by electric power applied from the outside, and the transmitter (or transducer) 200 includes the piezoelectric element 210, the ultrasonic waveguide 220 that transmits the ultrasonic waves produced from the piezoelectric element 210, a housing 230 into which the piezoelectric element 210 and the ultrasonic waveguide 220 are coupled integrally, and a power line 240 for applying the electric power to the piezoelectric element 210.

However, according to this configuration, relatively uniform distribution of sound pressure is periodically shown along a distance from the piezoelectric element within the near field, but the sound pressure is concentrated into the middle of the piezoelectric element and resultantly into the middle of the tip where the ultrasonic waves are finally transmitted to the object to be cleaned, as shown in FIG. 3, in the portion of the far field close to the near field.

In this case, not only the concentration of the sound pressure into the middle of the tip makes uniform cleaning difficult but also patterns in the portion cleaned by the portion where the sound pressure is concentrated may be damaged.

Lowering in the sound pressure to prevent the damage of the patterns deteriorates a cleaning efficiency.

Meanwhile, the conventional ultrasonic cleaning apparatus cannot remove foreign substances of various sizes effectively.

FIG. 4 is a graph showing a cleaning efficiency according to frequencies and particulate contaminant sizes in the conventional ultrasonic cleaning apparatus: a cleaning efficiency is high for large particulate contaminants and low for small particulate contaminants at 1 MHz, but the cleaning efficiency is low for large particulate contaminants and high for small particulate contaminants at 3 MHz.

That is, at a low frequency with a long wavelength, the large particulate contaminants are cleaned well but the small particulate contaminants of which number is large is poorly cleaned since cavitation is generated in a large size and the number of the cavitation is small.

On the contrary, at a high frequency with a short wavelength, the small particulate contaminants are cleaned well but the large particulate contaminants are poorly cleaned since small sized cavitation is produced in a large number and the shock wave produced at this time is weak.

Therefore, it is difficult for the conventional apparatus using a single frequency to clean the contaminants with different particulate sizes effectively.

Japanese Patent Registration No. 3927936 disclosed to solve the disadvantage of low cleaning efficiency in the case of employing a single frequency.

Japanese Patent Registration No. 3927936 includes, as shown in FIG. 5, a turn table 600 in which an upper portion of a support member is formed on a circular disc, and a plurality of ultrasonic oscillators 700, each of which is driven at different frequency from another one, are arranged parallel in a direction from the middle of the turn table to the periphery of the turn table.

That is, this technique is for cleaning different particulate contaminants efficiently by arranging ultrasonic oscillators parallel, which are driven at different frequencies from one another and have a rectangular shape long in a radial direction of a wafer W.

However, according to this technique, since a transverse wave is produced and the resulting peak sound pressure is shown in a longitudinal direction as the ultrasonic oscillator is long in the radial direction, distribution of the sound pressure is ununiform.

Consequently, fine patterns may be damaged by the peak sound pressure, and weakening of the vibration to reduce this peak sound pressure does not ensure the efficient cleaning

In addition, since the ultrasonic oscillators are not scanning type but fixed type despite the ununiform distribution of the sound pressure, it is impossible to improve the ununiform distribution of the sound pressure.

### DISCLOSURE

Technical Problem

An object of the present invention is to provide an ultrasonic precision cleaning apparatus, which supplies a cleaning solution to an object to be cleaned and transmits ultrasonic waves produced from a piezoelectric element to the supplied cleaning solution through an ultrasonic waveguide, wherein a vertical hole is formed in the middle of the piezoelectric element which forms a transmitter (or transducer) or the ultrasonic waveguide so that a sound pressure is not concentrated but is uniformly produced across wide area.

Another object of the present invention is to provide an ultrasonic precision cleaning apparatus, which allows uniform cleaning over the entire region of a rotating wafer by carrying out the cleaning while the transmitter (or transducer) moves in a scanning manner on the rotating wafer.

Further another object of the present invention is to provide an ultrasonic precision cleaning apparatus, which can increase a cleaning efficiency for contaminants with various particulate sizes by applying the ultrasonic waves to the object to be cleaned at at least two different frequencies using the transmitter (or transducer) driven at different frequencies from each other.

Technical Solution

To achieve the object of the present invention, the present invention provides an ultrasonic precision cleaning apparatus, which includes: a cleaning solution supplier for supplying a cleaning solution to an object to be cleaned; a piezoelectric element having a ceramic body and upper and lower electrodes respectively deposited to upper and lower portions of the ceramic body and producing ultrasonic waves, an ultrasonic waveguide coupled to a tip of the piezoelectric element, placed opposite to the object, to be cleaned and transmitting the ultrasonic waves produced from the piezoelectric element to the object to be cleaned wherein the piezoelectric element or the middle of the ultrasonic waveguide is formed with a vertical hole.

Advantageous Effects

In accordance with the present invention, as the vertical hole is formed in the middle of the piezoelectric element or the ultrasonic waveguide, high sound pressure is widely distributed around the vertical hole to thereby be able to enhance the cleaning efficiency.

Also, in accordance with the present invention, it is possible to increase the cleaning efficiency regardless of the size of the particulate contaminant by applying ultrasonic waves with different frequencies using the piezoelectric element driven at at least two different frequencies.

### DESCRIPTION OF DRAWINGS

The above and other objects, features and advantages of the present invention will become apparent from the following description of preferred embodiments given in conjunction with the accompanying drawings, in which:

FIG. 1 is a view showing a conventional ultrasonic cleaning apparatus.

FIG. 2 is a view showing another conventional ultrasonic cleaning apparatus.

FIG. 3 is a view showing distribution of sound pressure produced by a conventional ultrasonic cleaning apparatus.

FIG. 4 is a graph showing a cleaning efficiency according to frequencies and particulate contaminant sizes in a conventional ultrasonic cleaning apparatus.

FIG. 5 is a structural view showing a conventional single wafer ultrasonic cleaning apparatus using multiple frequencies.

FIG. 6 is an exploded perspective view of an ultrasonic precision cleaning apparatus in accordance with a first embodiment of the present invention.

FIGS. 7 to 9 and FIGS. 11 to 15 are views showing modified embodiments of the ultrasonic precision cleaning apparatus of FIG. 6.

FIG. 10 is a view showing arrangement of the piezoelectric element of FIG. 9.

FIG. 16 is an exploded perspective view of an ultrasonic precision cleaning apparatus in accordance with a second embodiment of the present invention.

FIGS. 17 to 23 are views showing modified embodiments of the ultrasonic precision cleaning apparatus of FIG. 16.

FIG. 24 is a graph showing improvement in distribution of peak sound pressure by the ultrasonic precision cleaning apparatus of the present invention.

FIG. 25 is a view showing distribution of sound pressure produced by the ultrasonic precision cleaning apparatus of the present invention.

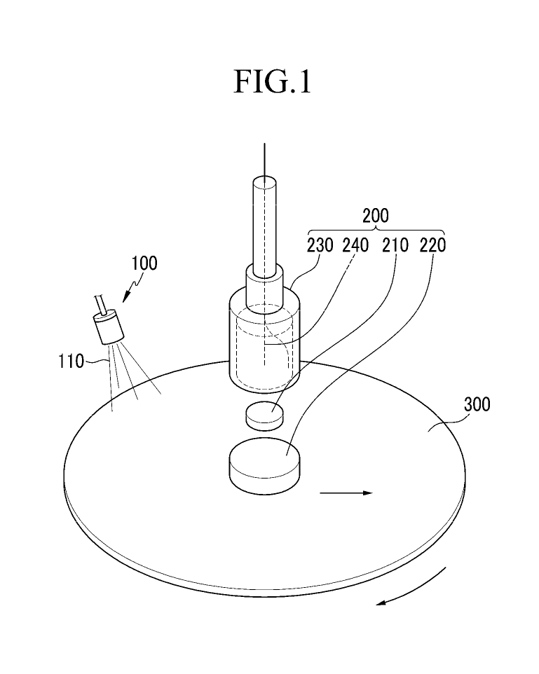

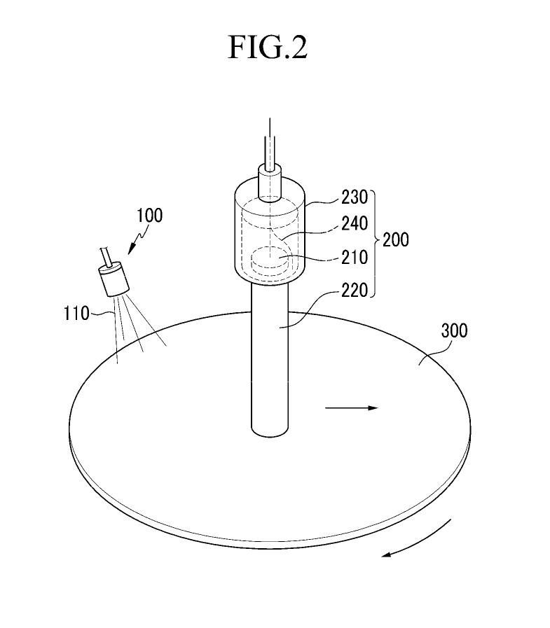

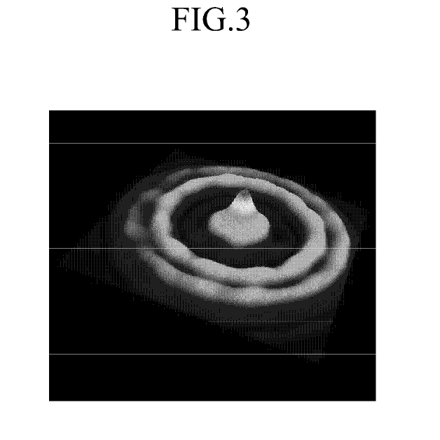

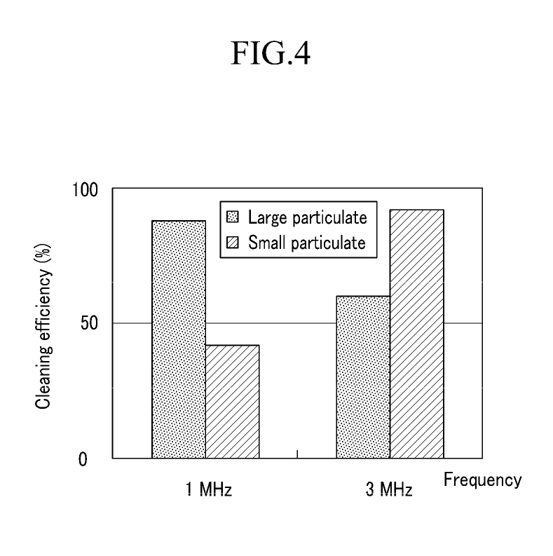

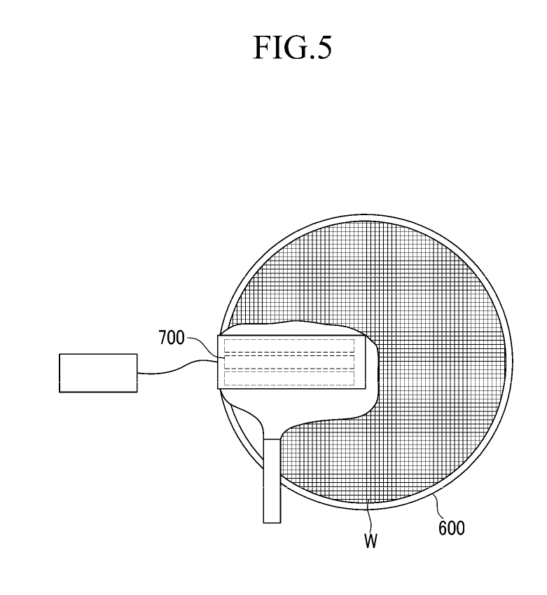

Detailed Description of Main Elements

| | |
|---|---|
| 1: cleaning solution supplier | 11: cleaning solution |
| 2: transmitter (or transducer) | 21: piezoelectric element |
| 21a: upper electrode | 21b: lower electrode |
| 21c: ceramic body | 211: vertical hole |
| 22: ultrasonic waveguide | 221: vertical hole |
| 23: housing | 24: power line |
| 3: object to be cleaned | |

### BEST MODE

Hereinafter, the embodiments of the present invention will be described in detail with reference to accompanying drawings.

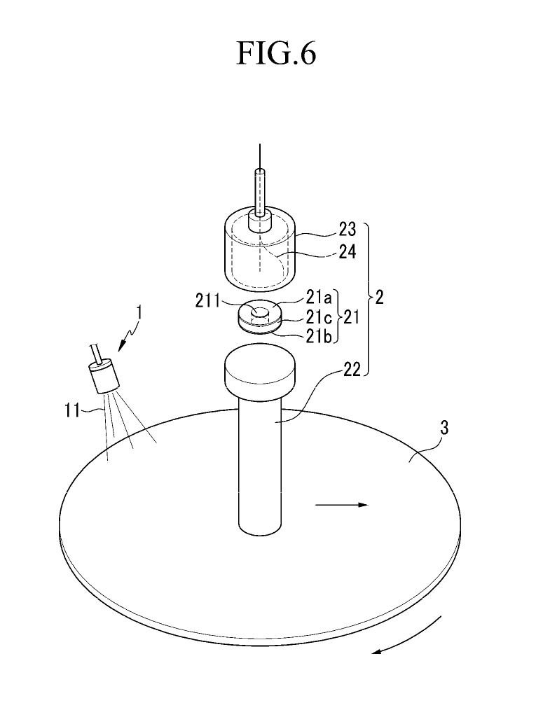

FIG. 6 is an exploded perspective view of an ultrasonic cleaning apparatus in accordance with a first embodiment of the present invention, and the ultrasonic cleaning apparatus in accordance with a first embodiment of the present invention includes a cleaning solution supplier 1 and a transmitter (or transducer) 2.

Herein, the cleaning solution supplier 1 is placed above an object to be cleaned 3 with a predetermined gap therebetween, and supplies a cleaning solution 11 to the object to be cleaned 3.

The transmitter (or transducer) 2 is placed opposite to the object to be cleaned 3 and produces ultrasonic waves, and the produced ultrasonic waves are transmitted to the object to be cleaned 3 through the cleaning solution.

At this time, the transmitter (or transducer) 2 includes an ultrasonic waveguide 22, a piezoelectric element 21 provided in the ultrasonic waveguide 22, a housing 23 and a power line 24, and moves on an upper surface of a wafer in a scanning manner to clean the entire surface of the rotating wafer uniformly.

Herein, the piezoelectric element 21 is that oscillates by electric power applied from the outside, and includes a ceramic body 21c and upper and lower electrodes respectively deposited on upper and lower surfaces of the ceramic body 21c.

Also, the piezoelectric element 21 and the ultrasonic waveguide 22 are coupled integrally to the housing 23, and the housing 23 is provided in an inside thereof with the power line 24 for applying the electric power to the piezoelectric element 21.

In accordance with a characteristic of the present invention, the piezoelectric element 21 is preferably formed of a vertical hole 211.

That is, as shown in FIG. 6, the vertical hole 211 may be formed so as to penetrate through the ceramic body 21c and the upper and lower electrodes 21a and 21b.

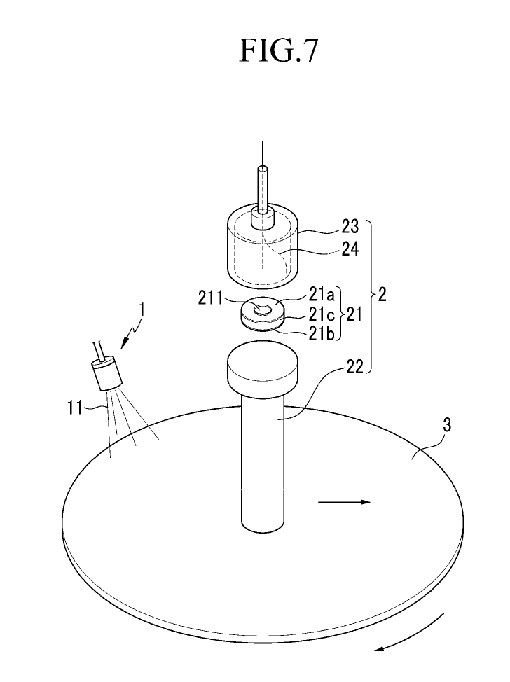

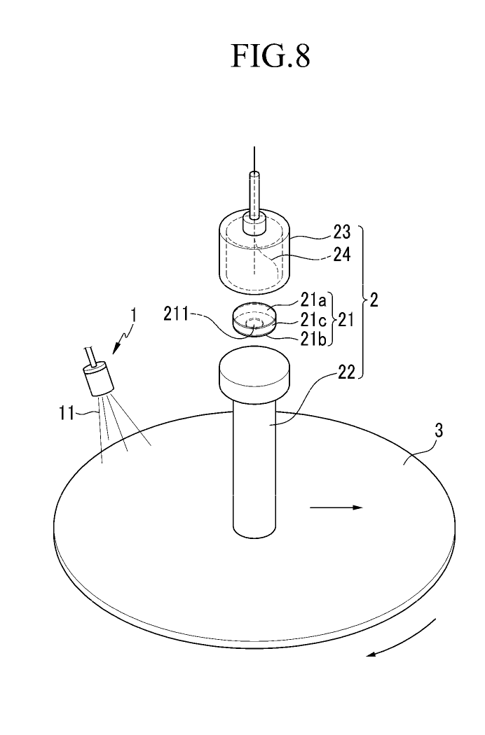

Alternatively, the vertical hole 211 may be formed in at least one middle of the upper and lower electrodes 21a and 21b in a shape that only the electrode layer except for the ceramic layer is removed: the vertical hole 211 is formed in the middle of the upper electrode 21a except for the ceramic body 21c as shown in FIG. 7 or in the middle of the lower electrode 21b except for the ceramic body 21c as shown in FIG. 8, or formed, as another modified embodiment, in both upper and lower electrodes 21a and 21b except for the ceramic body 21c.

In accordance with the first embodiment of the present invention as described above, as the vertical hole 211 is formed in the middle of the piezoelectric element 21, high sound pressure is widely distributed around the vertical hole 211 and is transmitted to the object to be cleaned 3 through the ultrasonic waveguide 22, to thereby be able to enhance the cleaning efficiency.

Also, in the first embodiment of the present invention, the piezoelectric element 21 may be driven at least two different frequencies.

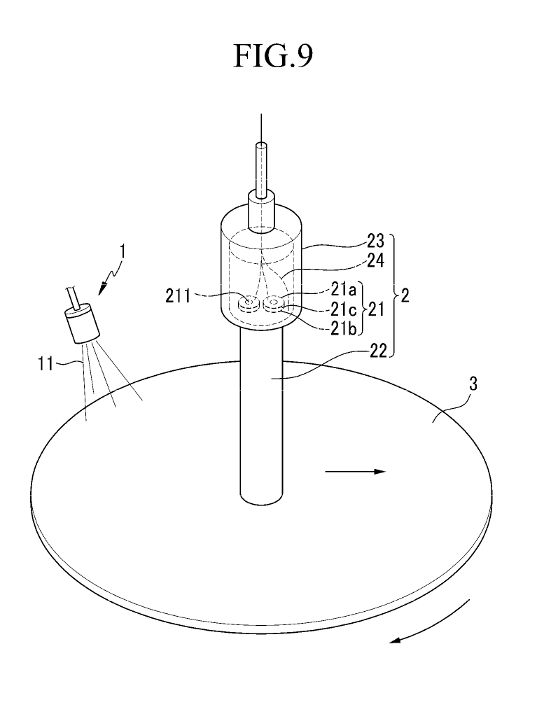

In accordance with a modified embodiment of the first embodiment of the present invention, as shown in FIG. 9, the piezoelectric elements 21 are provided in a number of at least two in the ultrasonic waveguide 22, and each piezoelectric element 21 may be driven at different frequencies from another one.

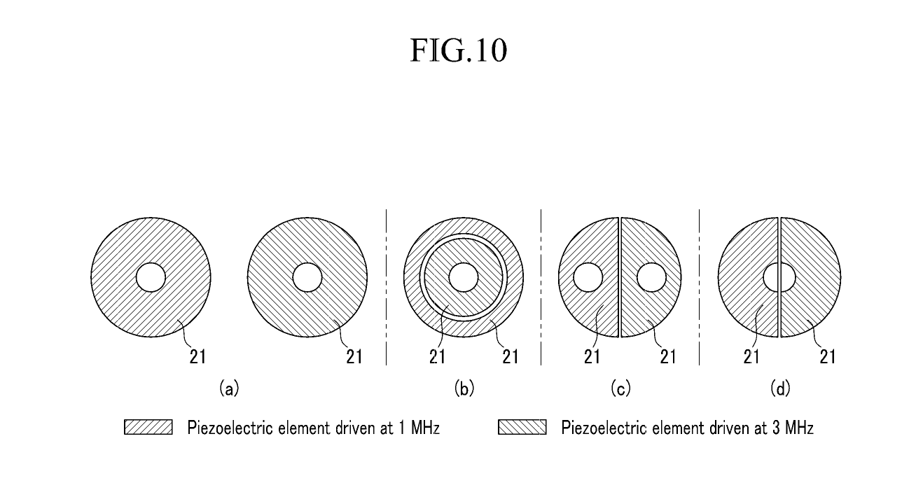

For example, the piezoelectric element may include a piezoelectric element 21 driven at 1 MHz and a piezoelectric element 21 driven at 3 MHz; the piezoelectric elements 21 have a circular shape and are spaced apart from each other as shown in (a) of FIG. 10, one piezoelectric element 21 is disposed outside with a ring shape and the other piezoelectric element 21 is disposed inside with a circular shape as shown in (b), or the piezoelectric elements 21 have a semi-circular shape and are spaced apart from and opposite to each other shown in (c) and (d).

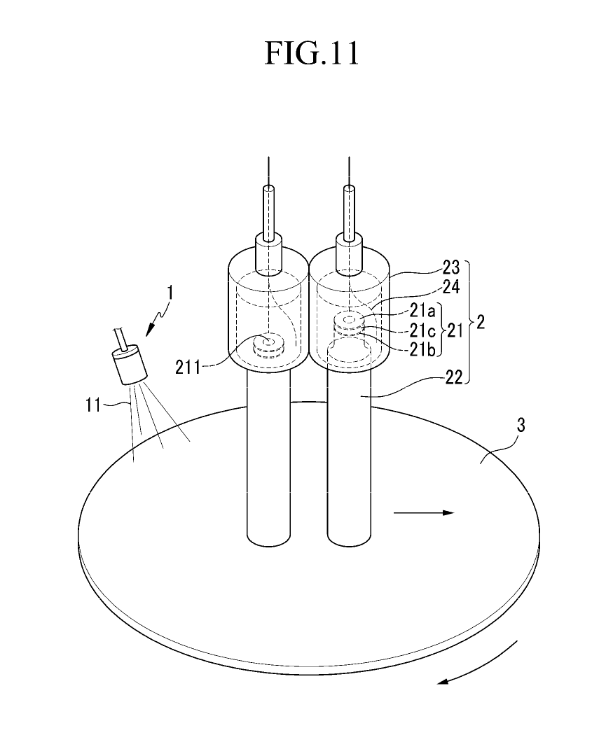

Also, the piezoelectric elements 21 may be placed at different heights from each other on the ultrasonic waveguide 22 as shown in FIG. 11.

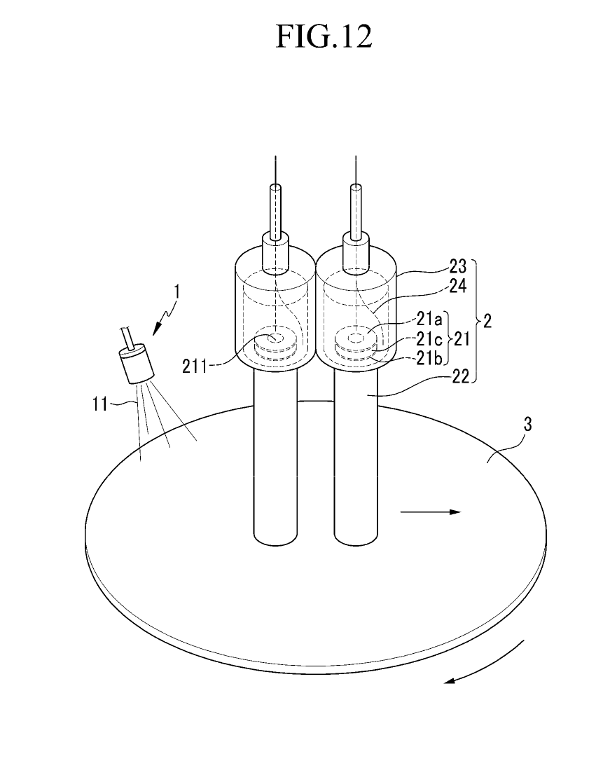

In accordance with another modified embodiment of the first embodiment of the present invention, the ultrasonic waveguides 22 may be provided in a number of at least two as shown in FIG. 12, each ultrasonic transmitter 22 may be provided with at least one piezoelectric element 21 and each piezoelectric element 21 may be driven at different frequency from another one.

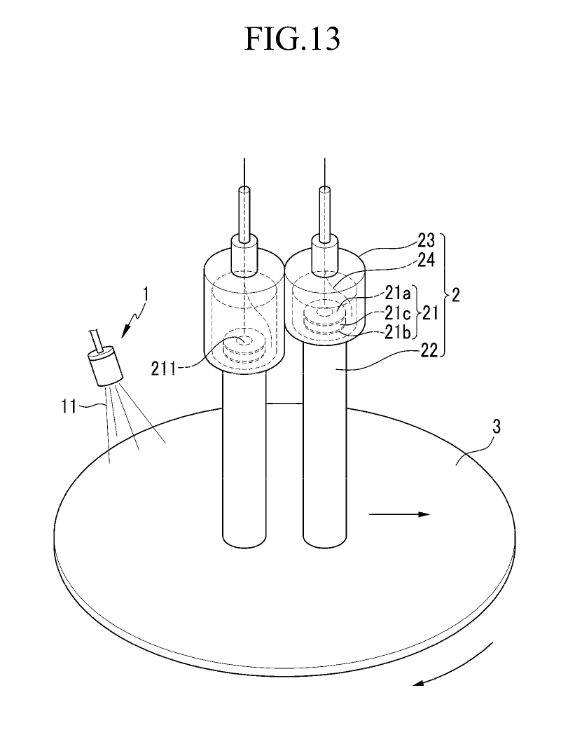

Also, as shown in FIG. 13, each ultrasonic waveguide may have different height from another one.

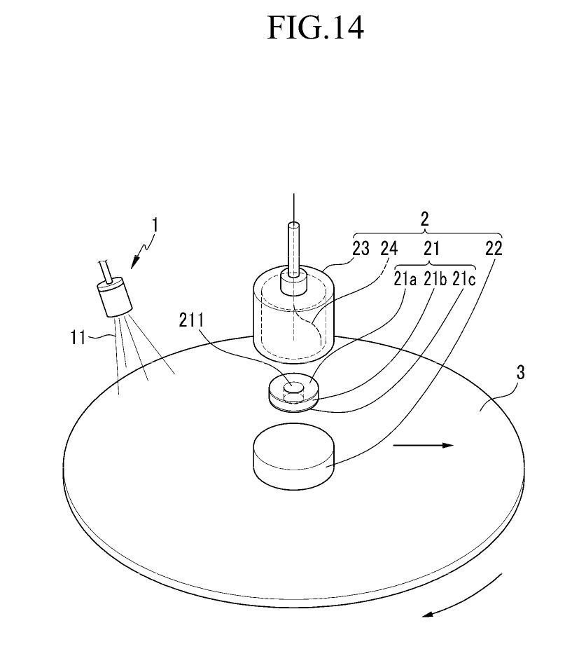

Meanwhile, although the ultrasonic waveguide 22 in the far field region transmits the ultrasonic waves produced from the piezoelectric element 21 in the first embodiment of the present invention, it is possible to transmit the ultrasonic waves through the ultrasonic waveguide in the near field region as shown in FIG. 14 and detailed description thereto will be omitted since the rest structure and modification other than the ultrasonic waveguide is the same as the first embodiment of the present invention as described above.

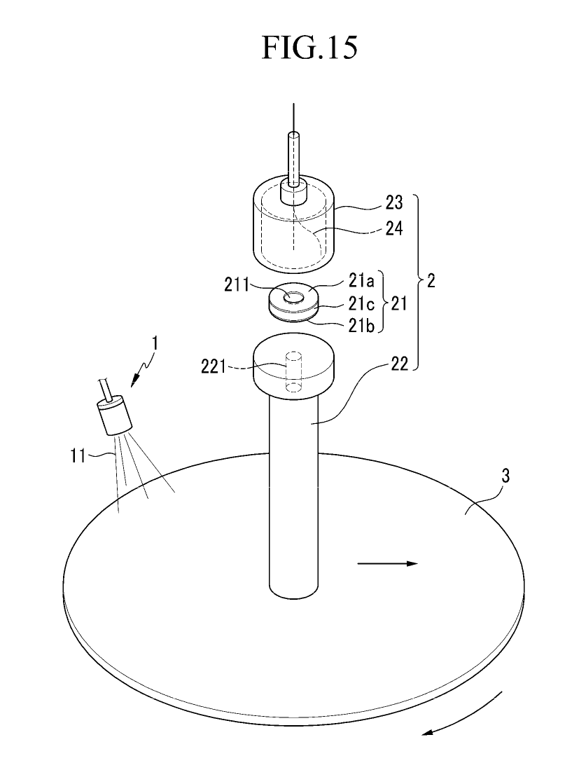

Also, although the vertical hole 211 is formed only in the middle of the piezoelectric element 21 in the first embodiment of the present invention, the vertical hole 211 may be formed in the middle of the ultrasonic waveguide 22 as shown in FIG. 15 in accordance with further aspect.

Further, although the vertical hole 221 of the ultrasonic waveguide 22 is herein formed in some upper portion of the ultrasonic transmitter 22, the vertical hole 221 may be formed in some lower portion of the ultrasonic waveguide 22 or formed so as to penetrate vertically through between the upper portion and the lower portion.

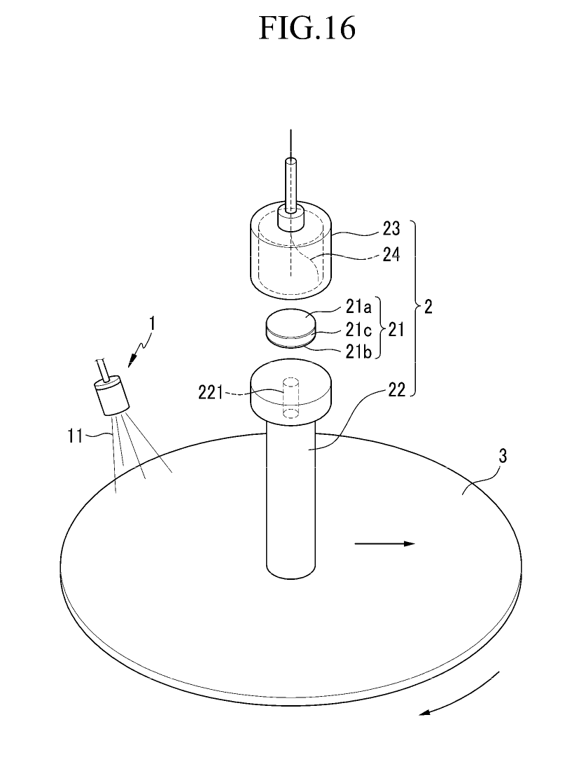

FIG. 16 is an exploded perspective view of an ultrasonic cleaning apparatus in accordance with a second embodiment of the present invention.

Referring to FIG. 16, the ultrasonic cleaning apparatus of the present invention includes the cleaning solution supplier 1 and the transmitter (or transducer) 2.

Herein, the cleaning solution supplier 1 is placed above the object to be cleaned 3 with a predetermined gap therebetween, and supplies the cleaning solution 11 to the object to be cleaned 3.

The transmitter (or transducer) 2 is placed opposite to the object to be cleaned 3 and produces ultrasonic waves, and the produced ultrasonic waves are transmitted to the object to be cleaned 3 through the cleaning solution.

At this time, the transmitter (or transducer) 2 includes an ultrasonic waveguide 22, a piezoelectric element 21 provided in the ultrasonic waveguide 22, a housing 23 and a power line 24, and moves on an upper surface of a wafer in a scanning manner to clean the entire surface of the rotating wafer uniformly.

That is, the existing transmitter (or transducer) is a stationary type and thus makes it difficult to clean the entire region of a rotating wafer uniformly with it, but in the present invention, it is possible to carry out uniform cleaning since the transmitter (or transducer) moves on and clean the rotating wafer in a scanning manner .

Herein, the piezoelectric element 21 is that oscillates by electric power applied from the outside, and includes a ceramic body 21c and upper and lower electrodes 21a and 21b respectively deposited on upper and lower surfaces of the ceramic body 21c.

Also, the piezoelectric element 21 and the ultrasonic waveguide 22 are coupled integrally to the housing 23, and the housing 23 is provided in an inside thereof with the power line 24.

In accordance with a characteristic of the present invention, the piezoelectric element 21 is preferably formed of a vertical hole 211 in the middle thereof.

That is, damage may be caused or the cleaning efficiency is lowered upon the cleaning of fine patterns as the ultrasonic waves produced from the piezoelectric element 21 are concentrated into the middle of the piezoelectric element 21, but in accordance with the first embodiment of the present invention, as the vertical hole 211 is formed in the middle of the piezoelectric element 21, high sound pressure is widely distributed around the vertical hole 211, to thereby be able to enhance the cleaning efficiency.

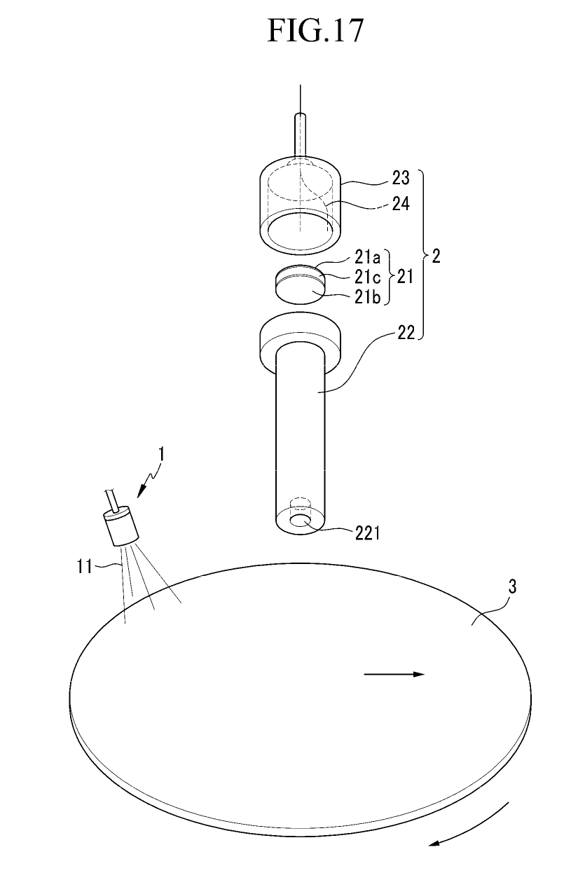

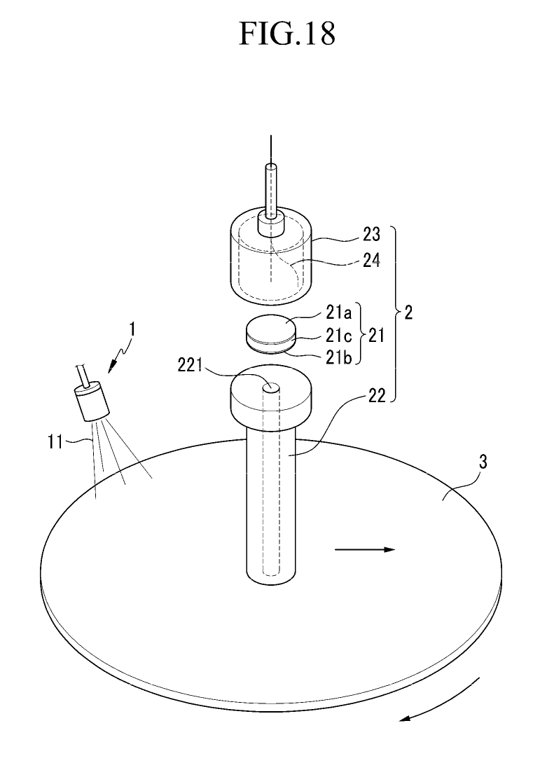

Although the vertical hole 221 of the ultrasonic waveguide 22 is formed in some upper portion of the ultrasonic waveguide 22 in FIG. 16, the vertical hole 221 may be formed in some lower portion of the ultrasonic waveguide 22 as shown in FIG. 17 or formed so as to penetrate vertically through between the upper portion and the lower portion as shown in FIG. 18.

Meanwhile, in the second embodiment of the present invention, the piezoelectric element 21 may be driven at at least two different frequencies.

That is, it is difficult to clean contaminants with different sizes efficiently if the piezoelectric element is driven at a single frequency, or uniform cleaning is not carried out by rotating wafer is stationary type or the fine patterns may be damaged by the portion where the peak sound pressure is strong as distribution of the sound pressure of the ultrasonic oscillator which is long in a longitudinal direction even if the piezoelectric element is driven at different frequencies, but the present invention moves the transmitter (or transducer) that produces different frequencies in a scanning manner to carry out uniform cleaning.

In other words, since cleaning efficiencies for the contaminant with large size particles and the contaminant with small size particles are different according to the frequency in cleaning using ultrasonic waves, it is required to apply different frequencies in the present invention in order to increase both cleaning efficiencies for the contaminant with large size particles and the contaminant with small size particles.

Therefore, the present invention can increase the cleaning efficiency regardless of the size of the particulate contaminant by using the piezoelectric element driven at least two different frequencies.

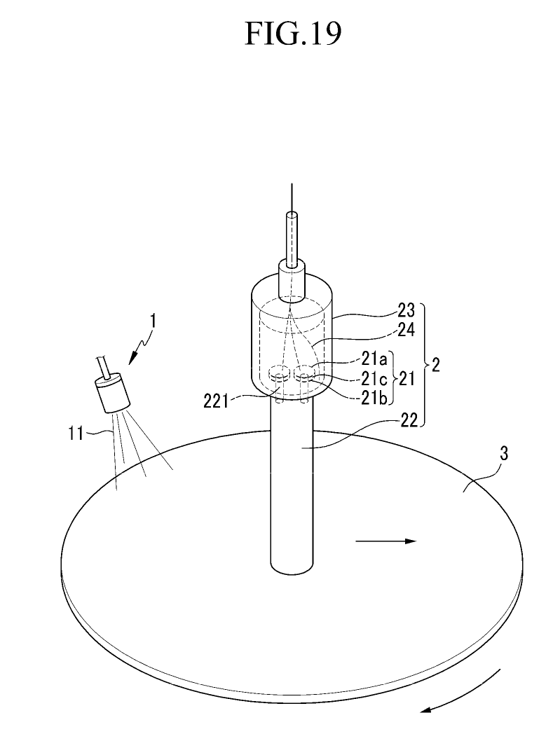

In another embodiment, as shown in FIG. 19, the ultrasonic waveguide 22 may he provided with at least two-piezoelectric elements 21 and each piezoelectric element 21 may be driven at different frequency from another one.

For detailed shape and arrangement of such piezoelectric elements 21, FIG. 10 and description to FIG. 10 may be referred.

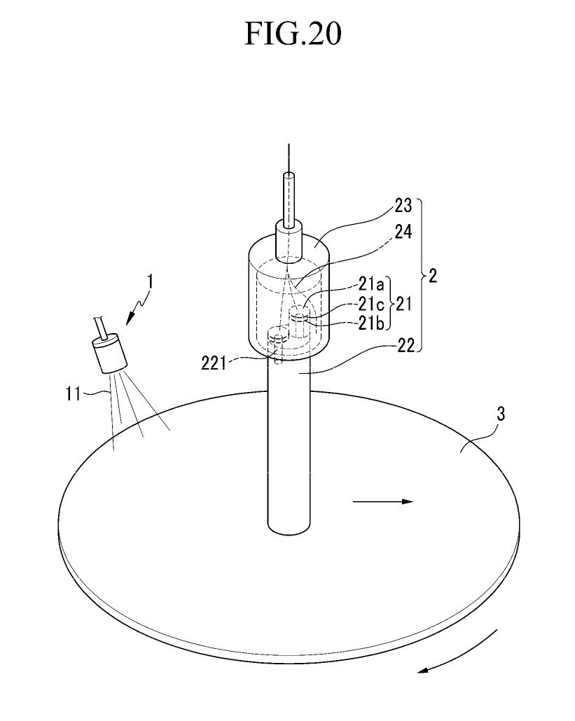

Herein, the piezoelectric elements 21 may be placed at different heights from each other on the ultrasonic waveguide 22 as shown in FIG. 20.

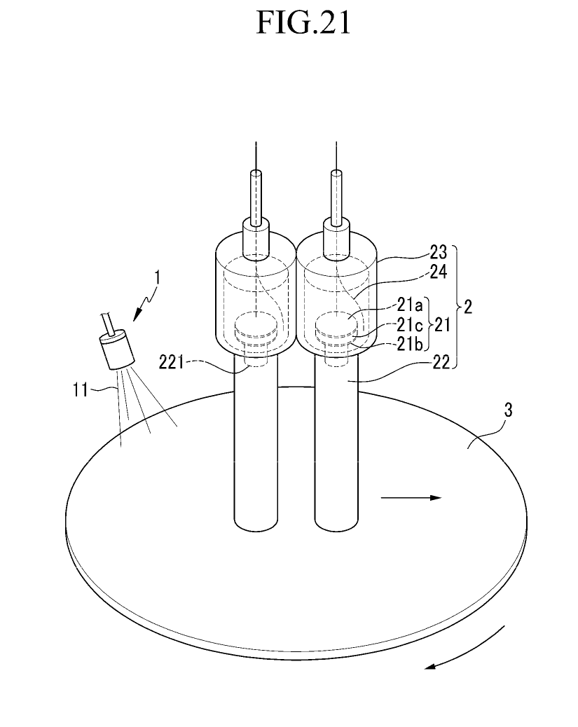

Alternatively, as shown in FIG. 21, the ultrasonic waveguides 22 may be provided in a number of at least two, each ultrasonic waveguide 22 may be provided with at least one piezoelectric element 21 and each piezoelectric element 21 may be driven at different frequency from another one.

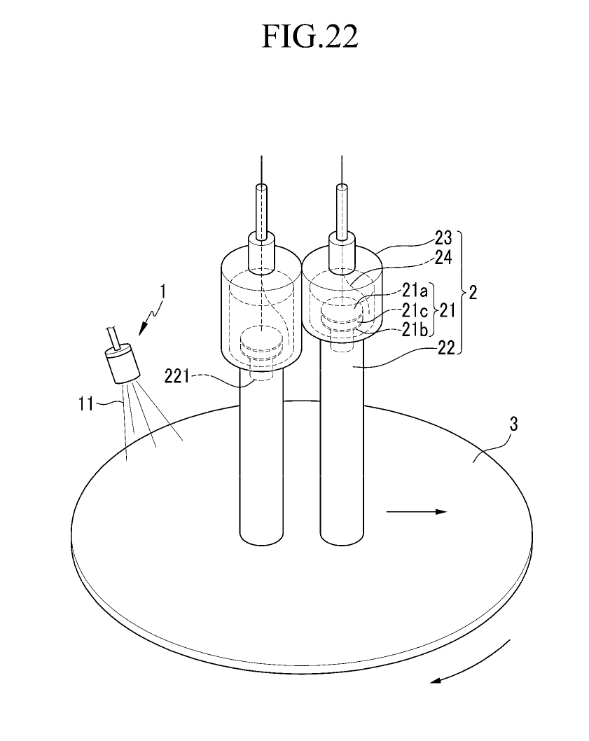

In a modified embodiment, each ultrasonic waveguide 22 may have different height from another one as shown in FIG. 22.

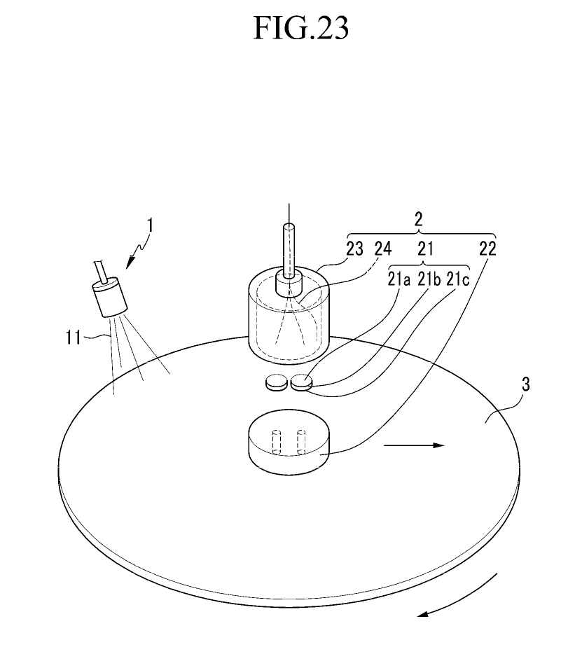

Meanwhile, although the ultrasonic waveguide 22 in the far field region transmits the ultrasonic waves produced from the piezoelectric element 21 in the second embodiment of the present invention, it is possible to transmit the ultrasonic waves through the ultrasonic waveguide in the near field region as shown in FIG. 23 and detailed description thereto will be omitted since the rest structure and modification other than the ultrasonic waveguide is the same as the second embodiment of the present invention as described above.

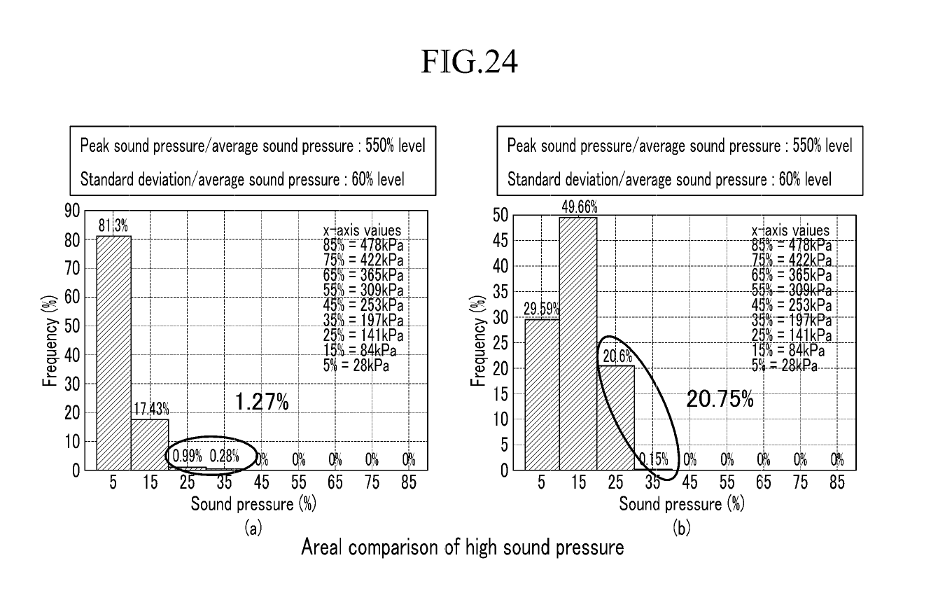

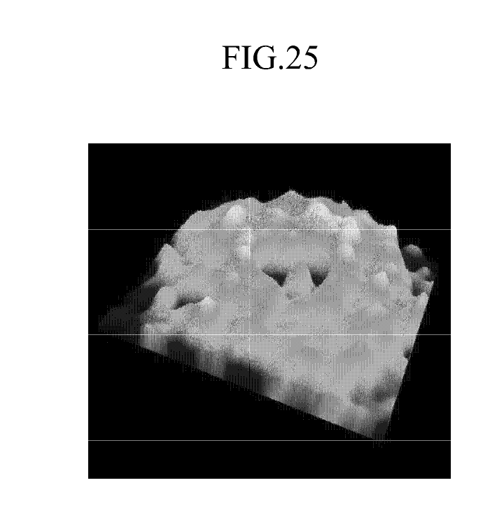

FIG. 24 is a graph showing improvement in distribution of the peak sound pressure by the ultrasonic precision cleaning apparatus in accordance with the present invention.

In FIG. 24, (a) shows areal distribution according to sections before improvement and (b) shows areal distribution according to sections after improvement, in which the x-axis indicates an intensity of the sound pressure and the y-axis indicates a frequency.

In (a), sound pressure of 10% or less is mainly distributed and high sound pressure of 20% or more is shown concentratively in the middle.

In (b), high sound pressure of 10% or more is evenly distributed without concentration into a specific portion.

As described above, the present invention can enhance the cleaning efficiency as the vertical hole is formed in the middle of the ultrasonic waveguide or the piezoelectric element and thus high sound pressure is widely distributed around the vertical hole.

The present application contains subject matter related to Korean Patent Application No. 10-2009-0023661, filed in the Korean Intellectual Property Office on Oct. 2, 2008, the entire contents of which is incorporated herein by reference.

While the present invention has been described with respect to the specific embodiments, it will be apparent to those skilled in the art that various changes and modifications may be made without departing from the spirit and scope of the invention as defined in the following claims.

1. An ultrasonic precision cleaning apparatus, comprising: a cleaning solution supplier for supplying a cleaning solution to an object to be cleaned (3); transmitter (or transducer) having a piezoelectric element (21) having a ceramic body (21c) and upper and lower electrodes (21a, 21b) respectively deposited to upper and lower portions of the ceramic body (21c) and producing ultrasonic waves, an ultrasonic waveguide (22) coupled to a tip of the piezoelectric element (21), placed opposite to the object to be cleaned (3) and transmitting the ultrasonic waves produced from the piezoelectric element (21) to the object to be cleaned (3), a housing (23) and a power line (24),wherein the piezoelectric element (21) is formed with a vertical hole (211).

2. The apparatus of claim 1, wherein the vertical hole (211) is formed so as to penetrate through the ceramic body (21c) and the upper and lower electrodes (21a, 21b).

3. The apparatus of claim 1, wherein the vertical hole (211) is formed in such a shape that only the electrode layer except for the ceramic layer is removed from at least one middle of the upper electrode and the lower electrode.

4. The apparatus of claim 1, wherein the ultrasonic waveguide (22) is further formed with the vertical hole (211) in the middle thereof.

5. The apparatus of claim 4, wherein the vertical hole (221) is formed in some upper portion or some lower portion, or formed so as to penetrate vertically through between the upper portion and the lower portion.

6. An ultrasonic precision cleaning apparatus, comprising; a cleaning solution supplier (1) for supplying a cleaning solution (11) to an object to be cleaned (3); transmitter (or transducer) having a piezoelectric element (21) having a ceramic body (21c) and upper and lower electrodes (21a, 21b) respectively deposited to upper and lower portions of the ceramic body (21c) and producing ultrasonic waves, an ultrasonic waveguide (22) coupled to a tip of the piezoelectric element (21), placed opposite to the object to be cleaned (3) and transmitting the ultrasonic waves produced from the piezoelectric element (21) to the object to be cleaned (3), a housing (23) and a power line (24),wherein the ultrasonic waveguide (22) is formed with a vertical hole in the middle thereof.

7. The apparatus of claim 6, wherein vertical hole (221) is formed in some upper portion or some lower portion of ultrasonic waveguide (22), or formed so as to penetrate vertically through between the upper portion and the lower portion.

8. The apparatus of claim 1, wherein the piezoelectric element (21) is driven at least two different frequencies.

9. The apparatus of claim 1, wherein the piezoelectric element (21) is provided in a number of at least two in the ultrasonic waveguide (22), and each piezoelectric element (21) is driven at different frequency from another one.

10. The apparatus of claim 9, wherein the piezoelectric elements (21) are placed at different heights on the ultrasonic waveguide (22).

11. The apparatus of claim 1, wherein the ultrasonic waveguide (22) is provided in a number of at least two, each ultrasonic waveguide (22) is provided with at least one piezoelectric element (21), and each piezoelectric element (21) is driven at different frequency from another one.

12. The apparatus of claim 1, wherein the ultrasonic waveguide (22) have different heights from each other.
